(19) United States
(12) Patent Application Publication
(10) Pub. No.: US 2006/0028227 A1
(43) Pub. Date: Feb. 9, 2006

(54) Self-isolation semiconductor wafer and test method thereof

(76) Inventors: Kil-Yeon Kim, Gyeonggi-do (KR); Hoo-Sung Kim, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/021,182

(22) Filed: Dec. 22, 2004

(30) Foreign Application Priority Data
Aug. 9, 2004 (KR) 2004-62429

(51) Int. Cl. G01R 31/02

(52) U.S. Cl. 324/763

(57) ABSTRACT

According to embodiments of the invention, during a test operation a semiconductor device where an overcurrent flows is detected from among a plurality of semiconductor devices formed on the semiconductor wafer. The power to the semiconductor device where the overcurrent flows may be automatically cut. Furthermore, an overcurrent detection result with respect to semiconductor devices disposed on the wafer is provided to a test apparatus.

### CROSS REFERENCE TO RELATED APPLICATIONS

This application claims priority from Korean Patent Application No. 2004-62429, filed on 9 Aug. 2004, the content of which is herein incorporated by reference in its entirety for all purposes.

### BACKGROUND OF THE INVENTION

1. Technical Field of the Invention This disclosure generally relates to semiconductor wafers and test methods thereof and, more specifically, to a semiconductor wafer capable of efficiently testing a wafer level and a test method thereof.

2. Description of the Related Art

In order to improve the reliability of semiconductor devices, various test methods may be utilized. The familiar burn-in test is frequently performed to detect potential or existing defects in semiconductor devices. The burn-in test is an aging test that is performed at a high temperature. The burn-in test applies a high temperature and pressure to each semiconductor device, intentionally causing the semiconductor device to operate under worst-case conditions. The burn-in test identifies the defective semiconductor devices. The semiconductor device may include a passive device, an active device, and an integration circuit. The semiconductor device, typically a small, thin, square-shaped semiconductor piece, may be referred to as a ‘die’ or a ‘chip’. In general, a plurality of semiconductor devices are regularly arranged in row and column directions on a wafer.

Recently, as burn-in test processes have been applied to a wafer level, methods that are capable of testing a plurality of semiconductor devices at one time have been suggested. For example, “INTEGRATED CIRCUIT CAPABLE OF BEING BURN-IN TESTED USING AN ALTERNATING CURRENT STRESS AND A TESTING METHOD USING THE SAME” is disclosed in U.S. Pat. No. 6,490,223 issued to Han et al. In the Han patent, a method of simultaneously performing a burn-in test with respect to a plurality of semiconductor devices is disclosed by arranging a power line for a burn-in test in a scribe lane region.

FIG. 1 is a diagram illustrating a semiconductor wafer having a conventional structure where a power line is arranged in a scribe lane region of the wafer.

With reference to FIG. 1, a number of semiconductor devices 100 are arranged on the semiconductor wafer. A number of scribe lane regions are arranged between the plurality of semiconductor devices 100. The scribe lane regions illustrated in FIG. 1 are arranged to separate the semiconductor devices 100 from the wafer. In the scribe lane regions of the wafer, there are no circuits. In the scribe lane regions, a number of burn-in power lines 10 are connected to a number of semiconductor devices 100, burn-in ground lines 20, and clock signal lines 30.

Since each of the lines 10, 20, and 30 that are arranged in the scribe lane region is commonly connected to the semiconductor devices 100, a stress (a burn-in power voltage) may be applied to the semiconductor devices 100 that are arranged on the wafer. Accordingly, it is possible to simultaneously perform a burn-in test with respect to an entire wafer so that the burn-in test time required for each device may be minimized.

However, if there is a defect in a specific semiconductor device, a burn-in test may be abnormally performed due to the defect. For example, if there is a defect (in particular, a defect such as a metallic bridge) of a specific semiconductor device during the burn-in test, an overcurrent that is more than a predetermined level flows in the pertinent semiconductor device. In this case, most of current that is used in the burn-in test flows to a defective semiconductor device, thereby reducing the burn-in test voltage that is applied to the wafer. As a result, the proper burn-in test voltage may not be applied to all the semiconductor devices that are being tested.

To solve this problem, a method for preventing a power from being supplied to a semiconductor device where an overcurrent flows is suggested in U.S. Pat. No. 6,133,054 by Henson et al. However, due to a physical characteristic of the fuse, this method is applicable only when a current that is more than several mA is detected. Therefore, this method is not applicable to a semiconductor devices where the overcurrents are less than several mA (e.g., several hundred A). In addition, this additional process for identifying a semiconductor device where an excessive current flows before performing a burn-in test causes the test time and the load of a test apparatus to be increased. Furthermore, it is difficult to confirm whether an appropriate test power is provided to semiconductor devices through an additional verification process.

### SUMMARY OF THE INVENTION

Some embodiments of the invention include a device capable of testing a semiconductor wafer more exactly and a test method thereof. Other embodiments of the invention include a device capable of minimizing a power consumption of the semiconductor wafer and a test method thereof. Still other embodiments of the invention include a device capable of selectively testing a normal semiconductor device from among a number of semiconductor devices arranged on a semiconductor wafer and a test method thereof.

### BRIEF DESCRIPTION OF THE DRAWINGS

FIG. 1 is a layout diagram illustrating a semiconductor wafer having a conventional structure where a power line is arranged in a scribe lane region of the wafer.

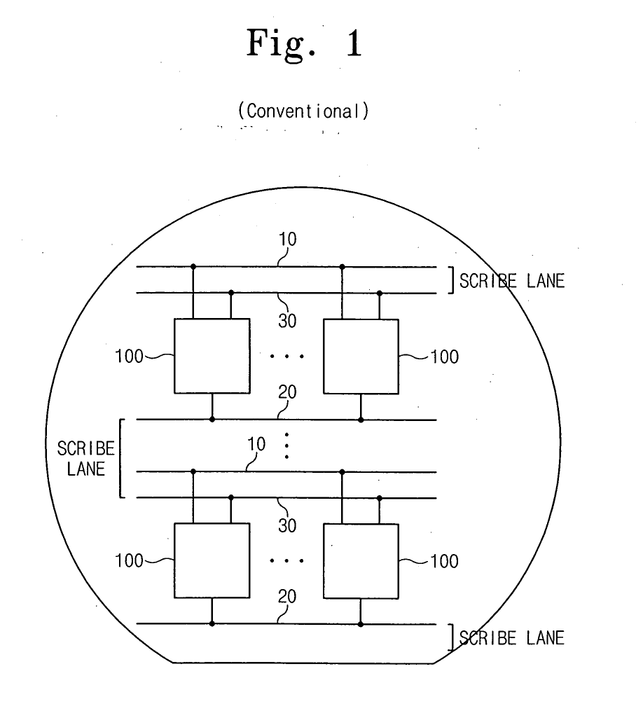

FIG. 2 is a layout diagram illustrating a semiconductor wafer having an improved scribe lane structure in accordance with some embodiments of the invention.

FIG. 3 is a circuit diagram further illustrating the power cut-off unit of FIG. 2.

FIG. 4 is a layout diagram illustrating a semiconductor wafer having an improved scribe-lane structure in accordance with other embodiments of the invention.

FIG. 5 is a circuit diagram further illustrating the power cut-off unit of FIG. 4.

FIG. 6 is a flowchart illustrating a method of testing the semiconductor wafer according to some other embodiments of the invention.

### DETAILED DESCRIPTION OF THE INVENTION

The invention will be described more fully below with reference to the accompanying drawings in which exemplary embodiments of the invention are shown.

While the invention is described below in connection with specific and preferred embodiments, it will be recognized that the described embodiments may be changed or modified by those of ordinary skill without departing from the inventive principles taught by the invention. Thus, the scope of the invention is not limited to the detailed description of the invention below, which is merely intended to be exemplary and illustrative, but rather comprehends the subject matter as defined by the attached claims.

According to some embodiments of the invention, in a semiconductor wafer and a test method thereof, a semiconductor device where an overcurrent flows is detected from among a number of semiconductor devices, which are formed on the semiconductor wafer during a test operation. Then, the power to the semiconductor device where the overcurrent is flowing is cut off automatically. Additionally, an overcurrent detection result with respect to the semiconductor devices on the semiconductor wafer may be output by a test apparatus.

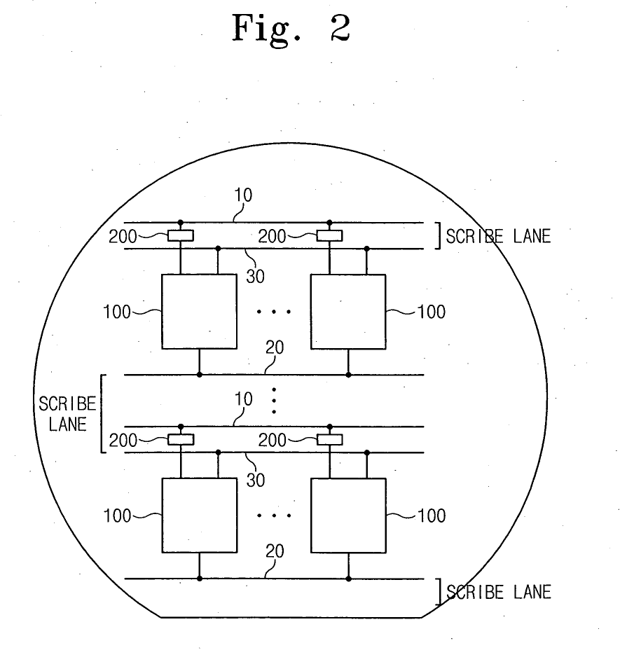

FIG. 2 is a layout diagram illustrating a semiconductor wafer having an improved scribe lane structure in accordance with some embodiments of the invention. The scribe lane structure of the semiconductor wafer shown in FIG. 2 is applicable for testing various semiconductor devices at the wafer level. Three typical kinds of methods for testing at wafer level include a burn-in test, a DC-current test, and a function test. For ease of explanation, a method for testing at wafer level will be described with reference to a burn-in test. However, the applicability of embodiments of the invention to a DC-current test and a function test should be apparent.

With reference to FIG. 2, a number of semiconductor devices 100 and a number of scribe lane regions are arranged on a wafer. A number of burn-in power lines 10, a number of burn-in ground lines 20, and a number of clock signal line 20 are arranged in the scribe lane regions. In this case, the number of burn-in power lines 10 are connected to the number of semiconductor devices 100.

Additionally, a power cut-off unit 200 is connected between the respective burn-in power lines 10 and the respective semiconductor devices 100. The power cut-off unit 200 detects a semiconductor device in which an overcurrent flows and then cuts an electric connection between the detected semiconductor device and the power lines automatically. As a result, it is possible to cut an overcurrent flowing to a defective semiconductor device and to minimize power consumption during the burn-in test. In addition, a burn-in test with respect to normal semiconductor devices can be performed selectively among the plurality of semiconductor devices arranged on the wafer.

The semiconductor device 100 shown in FIG. 2 may include a semiconductor device (e.g., a System-On-Chip (SOC)), such as a passive semiconductor device, an active semiconductor device, a semiconductor memory device, and an integrated circuit. The semiconductor device 100 may also include a volatile memory device or a non-volatile memory device.

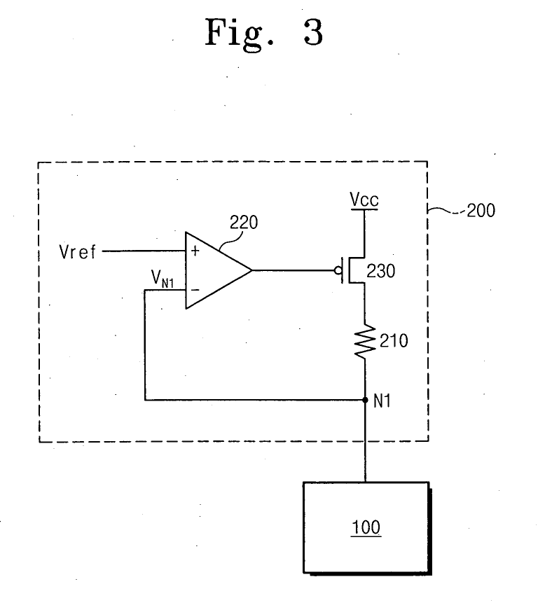

FIG. 3 is a circuit diagram further illustrating the power cut-off unit of FIG. 2. With reference to FIG. 3, the power cut-off unit 200 includes a voltage dropping unit 210, a comparator 220, and a switch unit 230.

The voltage dropping unit 210, shown in FIG. 3 as a resistor, drops a test power (a burn-in power Vcc) to a predetermined level. The comparator 220 compares a voltage (a voltage VN1 of the node N1) dropped by the voltage dropping unit 210 with a predetermined reference voltage Vref that is externally applied and then outputs a comparison result to the switch unit 230. The level of the reference voltage Vref may be controlled by users. By controlling the reference voltage Vref, various threshold levels at which a connection between the semiconductor device 100 and a test power is disconnected are possible without changing the structure of the power cut-off unit 200.

A switch unit 230 may include a switch device, e.g, such as the PMOS transistor illustrated in FIG. 3. The switch unit 230 switches a supply of a burn-in power Vcc in response to a comparison result generated from the comparator 220. For example, if a voltage exceeds a predetermined level in the voltage dropping unit 210, a voltage V1 of an internal node N1 is less than the reference voltage Vref. If the voltage V1 of the internal node N1 is less than the reference voltage Vref, the comparator 220 outputs a comparison result at a high level to the switch unit 230. The PMOS transistor that constitutes the switch unit 230 is turned off in response to the comparison result of the high level and consequently cuts off an electric connection between the semiconductor device 100 and the test power Vcc.

As previously mentioned, the power cut-off unit 200 performs a function as a magnetic shield in testing the semiconductor device. In other words, the power cut-off unit 200 detects a semiconductor device where an overcurrent flows from among the number of semiconductor devices on the semiconductor wafer without an external control. In addition, the power cut-off unit 200 self-cuts a power of the semiconductor device in which the overcurrent flows. In accordance with the constitution of the power cut-off unit 200, all overcurrents (e.g., several tens of mA, or several tens or several hundreds of uA) may be detected and cut off. In addition, the overcurrent detection level may be adjusted by controlling only a level of the reference voltage Vref, eliminating the need for constructing an additional circuit. As a result, it is possible to selectively perform a burn-in test with respect to normal semiconductor devices from among the semiconductor devices arranged on a wafer.

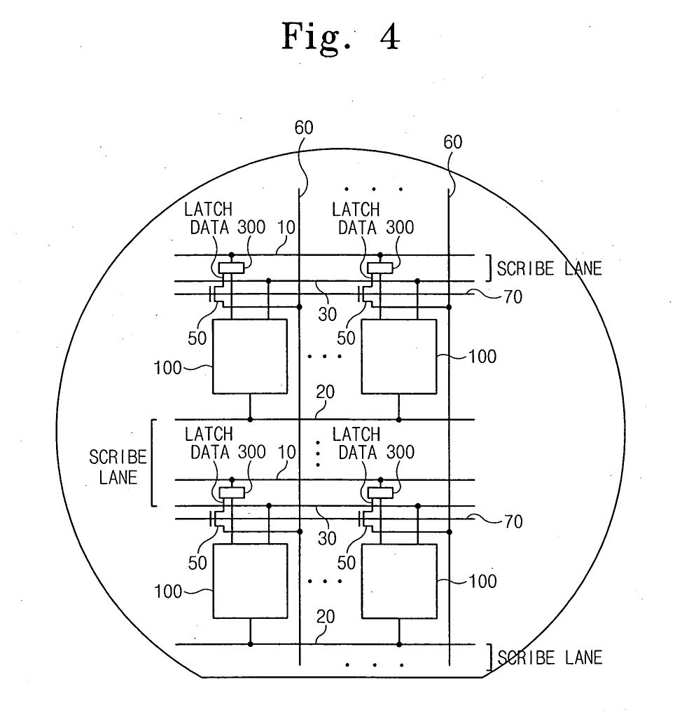

FIG. 4 is a layout diagram illustrating a semiconductor wafer having an improved scribe-lane structure in accordance with other embodiments of the invention. Referring to FIG. 4, a signal output unit 50 is connected to each of the power cut-off units 300. The signal output unit 50 outputs an overcurrent detection result (LATCH DATA) with respect to each of the semiconductor devices 100. The signal output unit 50 includes a switch device such as the MOS transistor shown in FIG. 4. The signal output unit 50 may be arranged in the power cut-off unit 300 or on outside of the power cut-off unit 300.

First and second output control lines 60 and 70 are laid out in row and column directions in each of the scribe lane regions. The first and second output control lines 60 and 70 control a signal output operation of the signal output unit 50.

The second output control line 70 is commonly connected to the control terminals (the gates of the MOS transistors) of the signal output units 50, which are arranged in the same row. In addition, the first output control line 60 is commonly connected to a current path of the signal output units 50, which are arranged in the same column. The signal output unit 50 outputs the overcurrent detection result (LATCH DATA) detected in each of the power cut-off units 300. As a result, a test apparatus can read the overcurrent detection result (LATCH DATA) that is output from each of the signal output units 50 through a row/column scan operation. At this time, location information by the respective semiconductor devices 100 is provided by the first and second output control lines 60 and 70 so that it is possible to confirm the overcurrent detection result (LATCH DATA) according to a location of each of the semiconductor devices 100. At this time, the overcurrent detection result may be output by a row or column unit according to a control signal, the control signal being input from the first and second output control lines 60 and 70 or output from a wafer unit.

In the event that an overcurrent is detected in a semiconductor device, this means that the semiconductor device 100 having the overcurrent is inadequate. Therefore, a test apparatus can detect whether the semiconductor device 100 is inadequate or not on the basis of the overcurrent detection result (LATCH DATA) without an additional test about an overcurrent. As a result, the test time is minimized, and the load of the test apparatus is reduced. Moreover, the test apparatus compares and analyzes the overcurrent detection result detected in testing the wafer and an overcurrent detection result in a normal operation. Accordingly, it is possible to compare a correlation of them.

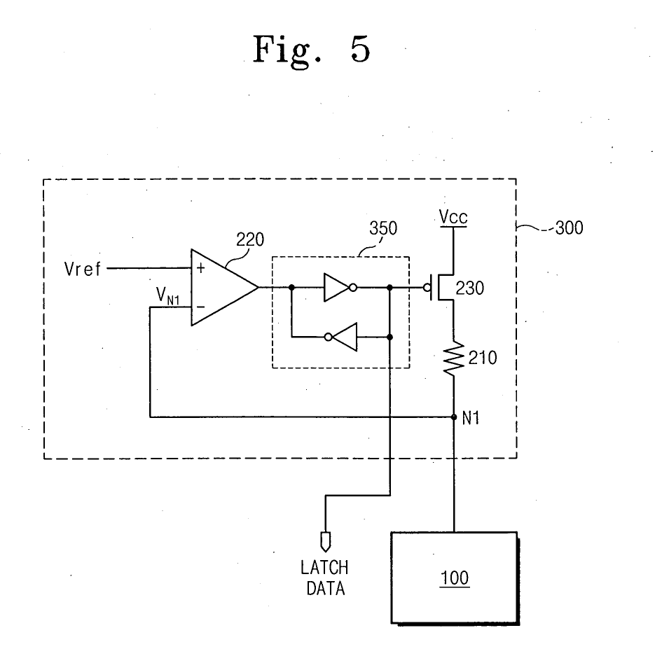

FIG. 5 is a circuit diagram further illustrating the power cut-off unit of FIG. 4. With reference to FIGS. 5 and 3, the power cut-off unit 300 of FIG. 5 has a similar structure as the power cut-off unit 200 of FIG. 3 except for the data latch unit 350. The similar circuit structure from FIGS. 3 and 5 is represented with like reference numerals. For ease of explanation, an unnecessarily duplicative description of the circuit elements that were already described with respect to FIG. 3 will be omitted.

In FIG. 5, the data latch unit 350 is connected between a comparator 220 and a switch unit 230. The data latch unit 350 latches overcurrent detection information with respect to each of the semiconductor devices 100, that is, a comparison result generated from the comparator 220. In addition, the latched comparison result is provided to signal output units 50 as an overcurrent detection result (LATCH DATA).

If a PMOS transistor of the switch unit 230 is turned off due to a detection of an overcurrent, there is a possibility that an internal node N1 is floated. To prevent the internal node N1 from floating, the overcurrent detection result (LATCH DATA) is outputted by laying out the data latch unit 350 between the comparator 220 and the switch unit 230. Therefore, the internal node N1 is not floated.

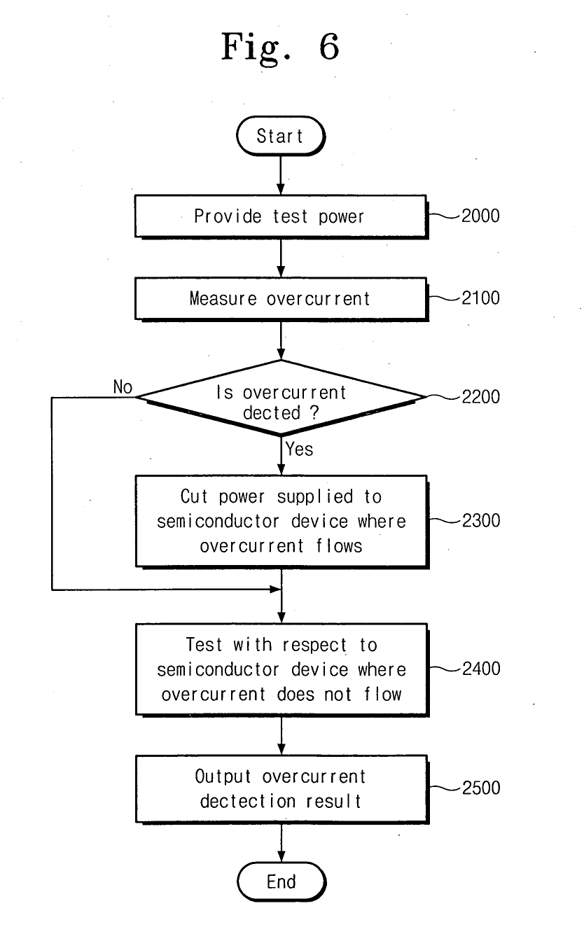

FIG. 6 is a flowchart illustrating a method of testing the semiconductor wafer according to some other embodiments of the invention.

With reference to FIG. 6, a test power is provided to each of the semiconductor devices 100 that are arranged on the semiconductor wafer in process 2000. The test power is applied to each of the semiconductor devices 100 through the power lines that are arranged in a scribe lane region of a wafer. After the test power is applied to each of the semiconductor devices 100, a number of voltage detection units 200 and 300 measure whether an overcurrent flows in each of the semiconductor devices 100 in process 2100. In this case, the plurality of voltage detection units 200 and 300 are arranged between the respective power lines 10 and the respective semiconductor devices 100. In order to measure an overcurrent, the voltage detection units 200 and 300 compare a voltage drop result VN1 with a predetermined reference result Vref. The voltage drop result VN1 means that a test power applied to the semiconductor device 100 is dropped to a predetermined level. In addition, whether an overcurrent flows in the respective semiconductor devices 100 is determined on the basis of the comparison result of process 2200

Depending on the detection result in process 2200, if there is the semiconductor device in which the overcurrent flows, the voltage detection units 200 and 300 self-cut a power of the semiconductor device without an external control in process 2300. Then, a test operation with respect to semiconductor devices where an overcurrent does not flow is performed in process 2400. A selective power supply and a test with respect to the semiconductor devices 100 are controlled by a switch operation of the voltage detection units 200 and 300.

If all test operations with respect to a memory device in which an overcurrent does not flow are performed in process 2400, the voltage detection unit 300 outputs an overcurrent detection result (LATCH DATA) detected in process 2200 to an external test apparatus in process 2500. As a result, the test apparatus previously acknowledges an inadequate semiconductor device 100. After that, the test apparatus instantly determines whether the semiconductor device 100 is inadequate or not on the basis of the overcurrent detection result (LATCH DATA) outputted in process 2400 without additionally testing an overcurrent. As a result, the test time is minimized, and a load of the test apparatus is reduced. Moreover, the test apparatus compares and analyzes the overcurrent detection result detected in testing the wafer and an overcurrent detection result in a normal operation. Accordingly, it is possible to compare and correlate the results.

The invention may be practiced in many ways. What follows are exemplary, non-limiting descriptions of some embodiments of the invention.

According to some embodiments of the invention, it is possible to detect an overcurrent flowing to the semiconductor device in a minute level as well as self-cut an overcurrent without an external control in testing semiconductor devices arranged on a wafer. In addition, a burn-in test with respect to normal semiconductor devices can be selectively performed among the semiconductor devices arranged on the wafer. Furthermore, an overcurrent detection result with respect to each of semiconductor devices may be directly provided to a test apparatus. Accordingly, it is possible to determine whether the individual semiconductor devices have defects without using an additional verification process.

According to some embodiments of the invention, a semiconductor wafer includes semiconductor devices formed on the wafer; a power line for transferring a test power to the semiconductor devices; and a power cut-off unit for detecting a semiconductor device where an overcurrent flows while the semiconductor devices are tested and for self-cutting an electric connection between the detected semiconductor device and the power line without an external control.

According to other embodiments of the invention, a semiconductor wafer includes semiconductor devices formed on the wafer; a power line for transferring a test power to the semiconductor devices; and a power cut-off unit for detecting a semiconductor device where an overcurrent flows while the semiconductor devices are tested and for self-cutting an electric connection between the detected semiconductor device and the power line without an external control. The power cut-off unit may output overcurrent detection information with respect to individual semiconductor devices to an external test apparatus in response to output control signals which are externally applied.

According to other embodiments of the invention, a semiconductor wafer includes semiconductor devices formed on the wafer; a power line for transferring a test power to the semiconductor devices; a power cut-off unit for detecting a semiconductor device where an overcurrent flows while the semiconductor devices are tested and for self-cutting an electric connection between the detected semiconductor device and the power line without an external control; a signal output unit for outputting overcurrent detection information detected from the power cut-off unit to an external output device; and first and second output control lines for transferring the control signals to the signal output unit.

In still other embodiments of the invention, a test method for a semiconductor wafer includes the processes of detecting whether a semiconductor device where an overcurrent flows is among the semiconductor devices that are laid out on the wafer while a test operation is performed with respect to a semiconductor wafer; selectively performing a test operation with respect to a semiconductor device where an overcurrent does not flow by self-cutting a power of the detected semiconductor device without an external control; and outputting an overcurrent detection result with respect to the semiconductor devices to an external test apparatus.

Changes may be made to the invention in light of the above detailed description. In general, in the following claims, the terms used should not be construed to limit the invention to the specific embodiments disclosed in the specification and the claims, but should be construed to include all methods and devices that are in accordance with the claims. Accordingly, the invention is not limited by the disclosure, but instead its scope is to be determined by the following claims.

We claim:

1. A semiconductor wafer comprising:
semiconductor devices formed on the wafer;
a power line for transferring a test power to the semiconductor devices; and
a power cut-off unit structured to detect a semiconductor device where an overcurrent flows while the semiconductor devices are tested and for self-cutting an electrical connection between the semiconductor device where the overcurrent flows and the power line without an external control.

2. The semiconductor wafer of claim 1, wherein the power cut-off unit comprises:
a voltage dropping unit structured to reduce the test power;
a comparator for structured to compare a voltage drop across the voltage dropping unit with a predetermined reference voltage; and
a switch unit structured to open the electrical connection when the voltage drop is greater than the predetermined reference voltage.

3. The semiconductor wafer of claim 2, wherein the predetermined reference voltage can be controlled.

4. The semiconductor wafer of claim 2, wherein the power cut-off unit further comprises a data latch unit structured to latch overcurrent detection information with respect to the semiconductor devices.

5. The semiconductor wafer of claim 4, further comprising a signal output unit structured to output the latched overcurrent detection information to a test apparatus.

6. The semiconductor wafer of claim 1, wherein the power cut-off unit is structured to exclude the detected semiconductor device from the test.

7. The semiconductor wafer of claim 1, wherein the power line is disposed in a scribe lane region between the semiconductor devices.

8. The semiconductor wafer of claim 1, wherein the power cut-off unit is structured to operate during a burn-in test, a DC-current test, or a function test.

9. A semiconductor wafer comprising:
semiconductor devices formed on a wafer;
a power line configured to transfer a test power to the semiconductor devices; and
a power cut-off unit configured to detect a semiconductor device where an overcurrent flows while the semiconductor devices are tested and configured to open an electrical connection between the detected semiconductor device and the power line without an external control, wherein the power cut-off unit outputs an overcurrent detection result with respect to the detected semiconductor device to an external test apparatus in response to externally applied output control signals.

10. The semiconductor wafer of claim 9, wherein the power cut-off unit comprises:
a voltage dropping unit configured to reduce the test power;
a comparator configured to compare a voltage drop across the voltage dropping unit with a predetermined reference voltage;
a switch unit configured to open the electrical connection when the voltage drop is above the predetermined reference voltage.

11. The semiconductor wafer of claim 9, wherein the predetermined reference voltage can be controlled.

12. The semiconductor wafer of claim 9, wherein the power cut-off unit is structured to exclude the detected semiconductor device from the test.

13. The semiconductor wafer of claim 9, wherein the power line is disposed in a scribe lane region between the semiconductor devices.

14. The semiconductor wafer of claim 9, further comprising first output control lines and second output control lines, the first and second output control lines configured to transfer the control signals to the power cut-off unit.

15. The semiconductor wafer of claim 14, wherein the first and second output control lines are disposed in a scribe lane region between the semiconductor devices.

16. The semiconductor wafer of claim 14, wherein the first and second output control lines are configured to provide location information about the detected semiconductor device to the test apparatus.

17. The semiconductor wafer of claim 9, wherein the power cut-off unit outputs the overcurrent detection result to a row/column unit or to a wafer unit in response to the output control signals.

18. The semiconductor wafer of claim 9, wherein the power cut-off unit is configured to detect the semiconductor device during a burn-in test, a DC-current test, or a function test.

19. A semiconductor wafer comprising:
semiconductor devices formed on the wafer;
a power line configured to supply a test power to the semiconductor devices;
a power cut-off unit configured to detect a semiconductor device where an overcurrent flows while the semiconductor devices are tested and configured to open an electrical connection between the detected semiconductor device and the power line without an external control;
a signal output unit configured to provide an overcurrent detection result to an external output device in response to the power cut-off unit; and
first and second output control lines for transferring the plurality of control signals to the signal output unit.

20. The semiconductor wafer of claim 19, wherein the power cut-off unit comprises:
a voltage dropping unit configured to reduce the test power;
a comparator configured to compare a voltage drop across the voltage dropping unit with a predetermined reference voltage and produce a comparison result;
a switch unit configured to open the electrical connection when the voltage drop passes a predetermined level; and
a data latch unit for storing the comparison result and outputting the stored comparison result as the overcurrent detection result to the signal output unit.

21. The semiconductor wafer of claim 20, wherein the reference voltage can be controlled.

22. The semiconductor wafer of claim 19, wherein the power cut-off unit is configured to exclude the semiconductor device detected by the power cut-off unit from the test.

23. The semiconductor wafer of claim 19, wherein the power line and the first and second output control lines are disposed in a scribe lane region between the semiconductor devices.

24. The semiconductor wafer of claim 19, wherein the first and second output control lines are configured to provide location information about the semiconductor devices on the wafer to the external output device.

25. The semiconductor wafer of claim 19, wherein the signal output unit outputs the overcurrent detection result to a row/column unit or a wafer unit in response to the output control signals.

26. The semiconductor wafer of claim 19, wherein the power cut-off unit is configured to detect the semiconductor device during a burn-in test, a DC-current test, or a function test.

27. A method of testing a semiconductor wafer comprising:
detecting a semiconductor device where an overcurrent condition exists from among semiconductor devices that are disposed on the semiconductor wafer and that are commonly connected to a power line while a test operation is performed with respect to the semiconductor wafer;
maintaining an adequate power level to a semiconductor device that is not in an overcurrent condition by automatically disconnecting the detected semiconductor device from the power line without an external control; and
outputting an overcurrent detection result for the semiconductor devices to an external test apparatus.

28. The method of claim 27, wherein detecting the semiconductor device comprises:
measuring a voltage drop across the semiconductor device; and
comparing the voltage drop with a predetermined reference voltage.

29. The method of claim 28, wherein maintaining an adequate power level comprises opening an electric connection between the detected semiconductor device and the power line when the voltage drop exceeds the predetermined reference voltage.
